(19) United States
(12) Patent Application Publication
(10) Pub. No.: US 2025/0364368 A1
(43) Pub. Date: Nov. 27, 2025

(54) SEMICONDUCTOR DEVICE AND POWER CONVERSION DEVICE

(71) Applicant: Mitsubishi Electric Corporation, Tokyo (JP)

(72) Inventors: Akira KOSUGI, Chiyoda-ku, Tokyo (JP); Hodaka ROKUBUICHI, Chiyoda-ku, Tokyo (JP); Wakana MASUDA, Chiyoda-ku, Tokyo (JP); Shota MORI, Chiyoda-ku, Tokyo (JP); Kozo HARADA, Chiyoda-ku, Tokyo (JP); Kei YAMAMOTO, Chiyoda-ku, Tokyo (JP)

(73) Assignee: Mitsubishi Electric Corporation, Tokyo (JP)

(21) Appl. No.: 18/867,811

(22) PCT Filed: Jun. 28, 2022
(86) PCT No.: PCT/JP2022/025735

§ 371 Date: Nov. 21, 2024

(51) Int. Cl. H01L 23/473; H01L 21/56; H01L 23/00; H01L 23/31; H01L 23/495

(52) U.S. Cl. CPC H01L 23/473; H01L 23/3121; H01L 21/56; H01L 23/49562; H01L 24/32; H01L 24/48; H01L 24/73; H01L 2224/32245; H01L 2224/48245; H01L 2224/73215; H01L 2224/73265

(57) ABSTRACT

A semiconductor device includes: a heat spreader; a semiconductor element; a cooler; an insulating layer; and a sealing member. The heat spreader has a first surface and a second surface opposite to the first surface. The semiconductor element has a third surface and a fourth surface opposite to the third surface, and is disposed such that the fourth surface faces the first surface. The cooler is disposed to face the first surface with the insulating layer interposed therebetween. A flow path through which refrigerant flows is provided inside the cooler. The sealing member seals the heat spreader, the semiconductor element and the cooler. In a plan view, a projected area of the cooler is equal to or less than a projected area of the heat spreader.

### TECHNICAL FIELD

The present disclosure relates to a semiconductor device and a power conversion device.

### BACKGROUND ART

For example, Japanese Patent Laying-Open No. 2018-182105 (PTL 1) describes a semiconductor device. The semiconductor device described in PTL 1 has a cooler, a semiconductor element, a lead frame, and a sealing member. The cooler has a first main surface and a second main surface opposite to the first main surface. An element pattern layer is disposed on the first main surface. A flow path through which refrigerant flows is provided inside the cooler.

The semiconductor element has a front surface and a rear surface. The semiconductor element is disposed on the element pattern layer. An electrode on the rear surface of the semiconductor element is electrically connected to the element pattern layer by a first bonding material. One end of the lead frame is electrically connected to an electrode on the front surface of the semiconductor element by a second bonding material. The other end of the lead frame is electrically connected to the element pattern layer by a third bonding material. The cooler, the semiconductor element and the lead frame are sealed by a sealing member.

### CITATION LIST

### Patent Literature

PTL 1: Japanese Patent Laying-Open No. 2018-182105

### SUMMARY OF INVENTION

### Technical Problem

In the semiconductor device described in PTL 1, heat generated from the semiconductor element is transferred through the first bonding material and the element pattern layer and released in the cooler. However, in the semiconductor device described in PTL 1, the cooler is large in size and downsizing is difficult.

The present disclosure has been made in view of the problems of the prior art as described above. More specifically, the present disclosure provides a semiconductor device capable of achieving both high cooling capacity and downsizing.

### Solution to Problem

A semiconductor device of the present disclosure includes: a heat spreader; a semiconductor element; a cooler; an insulating layer; and a sealing member. The heat spreader has a first surface and a second surface opposite to the first surface. The semiconductor element has a third surface and a fourth surface opposite to the third surface, and is disposed such that the fourth surface faces the first surface. The cooler is disposed to face the first surface with the insulating layer interposed therebetween. A flow path through which refrigerant flows is provided inside the cooler. The sealing member seals the heat spreader, the semiconductor element and the cooler. In a plan view, a projected area of the cooler is equal to or less than a projected area of the heat spreader.

### Advantageous Effects of Invention

According to the semiconductor device of the present disclosure, high cooling capacity and downsizing can be both achieved.

### BRIEF DESCRIPTION OF DRAWINGS

FIG. 1 is a plan view of a semiconductor device 100A.

FIG. 2 is a cross-sectional view taken along II-II in FIG. 1.

FIG. 3 is a plan view of semiconductor device 100A according to a modification.

FIG. 4 is a manufacturing process diagram for semiconductor device 100A.

FIG. 5 is a cross-sectional view of a semiconductor device 100B.

FIG. 6 is a cross-sectional view of a semiconductor device 100C.

FIG. 7 is a plan view of a semiconductor device 100D.

FIG. 8 is a plan view of a semiconductor device 100E.

FIG. 9 is a plan view of semiconductor device 100E according to a modification.

FIG. 10 is a block diagram showing a configuration of a power conversion system 200.

### DESCRIPTION OF EMBODIMENTS

Details of embodiments of the present disclosure will be described with reference to the drawings. In the following drawings, the same or corresponding portions are denoted by the same reference characters, and the same description will not be repeated. The embodiments described below may be applied in combination as appropriate.

### First Embodiment

A semiconductor device according to a first embodiment will be described. The semiconductor device according to the first embodiment is referred to as a semiconductor device 100A.

### (Configuration of Semiconductor Device 100A)

A configuration of semiconductor device 100A will be described below.

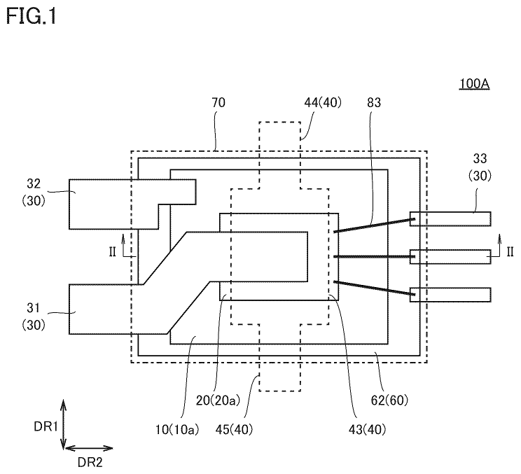

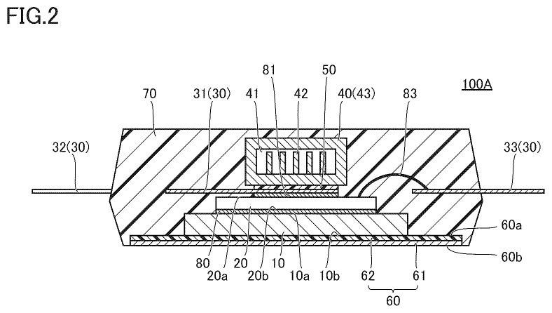

FIG. 1 is a plan view of semiconductor device 100A. In FIG. 1, a cooler 40 is indicated by a dotted line, and a sealing member 70 is indicated by a dash-dot line. FIG. 2 is a cross-sectional view taken along II-II in FIG. 1. FIG. 2 shows a cross section of semiconductor device 100A orthogonal to a first direction DR1 described below. As shown in FIGS. 1 and 2, semiconductor device 100A has a heat spreader 10, a semiconductor element 20, a lead frame 30, cooler 40, an insulating layer 50, an insulating sheet 60, and sealing member 70.

Heat spreader 10 has a first surface 10a and a second surface 10b. First surface 10a and second surface 10b are end faces of heat spreader 10 in a thickness direction. Second surface 10b is opposite to first surface 10a. Heat spreader 10 is, for example, a copper plate. Heat spreader 10 is formed by a press molding method, for example. Dimple-shaped projections and recesses may be formed on a surface of heat spreader 10. As a result, adhesiveness to sealing member 70 is improved, and separation of sealing member 70 from heat spreader 10 caused by thermal stress generated by heat generation during operation of semiconductor device 100A is suppressed.

Semiconductor element 20 has a third surface 20a and a fourth surface 20b. Third surface 20a and fourth surface 20b are end faces of semiconductor element 20 in the thickness direction. Fourth surface 20b is opposite to third surface 20a. Semiconductor element 20 is, for example, an insulated gate bipolar transistor (IGBT). Semiconductor element 20 has a first electrode and a second electrode on third surface 20a, and has a third electrode on fourth surface 20b. When semiconductor element 20 is an IGBT, the first electrode and the second electrode are an emitter electrode and a gate electrode, respectively, and the third electrode is a collector electrode. Each of the first electrode, the second electrode and the third electrode is made of, for example, an aluminum alloy containing aluminum or silicon. Semiconductor element 20 is formed using a semiconductor substrate. The semiconductor substrate is made of a semiconductor material such as silicon, silicon carbide, gallium nitride, or diamond. Semiconductor element 20 is used in an inverter portion that converts DC power into AC power, for example.

Semiconductor element 20 is disposed on heat spreader 10. More specifically, semiconductor element 20 is disposed such that fourth surface 20b faces first surface 10a. Fourth surface 20b is electrically connected to first surface 10a by a bonding material 80. Thereby, the third electrode of semiconductor element 20 is electrically connected to heat spreader 10. Bonding material 80 is made of, for example, a solder alloy or sintered silver particles.

Lead frame 30 has a lead portion 31, a lead portion 32 and a plurality of lead portions 33. Lead frame 30 is formed by press-molding a copper plate, for example. Although not shown, dimple-shaped projections and recesses may be formed on a surface of lead frame 30. As a result, adhesiveness to sealing member 70 is improved, and separation of sealing member 70 from lead frame 30 caused by thermal stress generated by heat generation during operation of semiconductor device 100A is suppressed. A thickness of lead frame 30 is preferably smaller than a thickness of heat spreader 10.

Lead portion 31 is electrically connected to semiconductor element 20. More specifically, lead portion 31 is electrically connected to the first electrode of semiconductor element 20 by a bonding material 81. Bonding material 81 is made of, for example, a solder alloy or sintered silver particles. Lead portion 32 is electrically connected to heat spreader 10. More specifically, lead portion 32 is electrically connected to first surface 10a by a bonding material 82 (not shown). Bonding material 82 is made of, for example, a solder alloy or sintered silver particles.

Each of lead portions 33 is electrically connected to semiconductor element 20. More specifically, each of lead portions 33 is electrically connected to the second electrode of semiconductor element 20 by wire bonding using a wire 83. Wire 83 is made of, for example, copper, iron, nickel, cobalt, aluminum, or an alloy thereof.

A flow path 41 is provided inside cooler 40. Refrigerant flows through flow path 41. Although the refrigerant is, for example, water, the refrigerant is not limited thereto. A fin 42 is provided inside cooler 40 in order to enhance the cooling efficiency. Instead of fin 42, a pin may be provided inside cooler 40. Cooler 40 is made of, for example, aluminum, copper or the like.

Cooler 40 has a main body portion 43, a connection portion 44 and a connection portion 45. Main body portion 43 is disposed to face third surface 20a with a space therebetween. In a plan view, the refrigerant flows inside flow path 41 in main body portion 43 along first direction DR1. It should be noted that the plan view refers to a view when semiconductor device 100A is seen from a direction orthogonal to third surface 20a.

Connection portion 44 is connected to one end of main body portion 43 in first direction DR1. Connection portion 45 is connected to the other end of main body portion 43 in first direction DR1. Connection portion 44 and connection portion 45 extend along first direction DR1 in a plan view. Hoses are connected to connection portion 44 and connection portion 45, for example. For example, the refrigerant is supplied from the hose connected to connection portion 44. The refrigerant flows through flow path 41 in connection portion 44 and then flows through flow path 41 in main body portion 43. The refrigerant having flown through flow path 41 in main body portion 43 flows through flow path 41 in connection portion 45 and is discharged from the hose.

In a plan view, a projected area of cooler 40 is equal to or less than a projected area of heat spreader 10. In a cross-sectional view orthogonal to first direction DR1, a width of cooler 40 (main body portion 43) is preferably equal to or less than a width of heat spreader 10.

Insulating layer 50 is interposed between third surface 20a and cooler 40. More specifically, insulating layer 50 is interposed between third surface 20a having lead frame 30 (lead portion 31) connected thereto and cooler 40. Cooler 40 and semiconductor element 20 (lead frame 30) are electrically insulated by insulating layer 50. Insulating layer 50 is made of, for example, a thermosetting resin such as an epoxy resin. The thermosetting resin may contain a filler. The filler is made of, for example, silica, alumina, boron nitride or the like.

Insulating sheet 60 has a fifth surface 60a and a sixth surface 60b. Fifth surface 60a and sixth surface 60b are end faces of insulating sheet 60 in the thickness direction. Sixth surface 60b is opposite to fifth surface 60a. Insulating sheet 60 has a metal layer 61 and an insulating layer 62. Metal layer 61 and insulating layer 62 are superimposed on each other. Fifth surface 60a is constituted by insulating layer 62 and sixth surface 60b is constituted by metal layer 61. Metal layer 61 is, for example, a copper foil, a copper plate, an aluminum plate or the like. Insulating layer 62 is made of, for example, a thermosetting resin such as an epoxy resin. The thermosetting resin may contain a filler. The filler is made of, for example, silica, alumina, boron nitride or the like. Heat spreader 10 is disposed on insulating sheet 60 such that second surface 10b faces fifth surface 60a.

Sealing member 70 seals heat spreader 10, semiconductor element 20, lead frame 30, cooler 40, insulating layer 50, and insulating sheet 60. Metal layer 61 is exposed from sealing member 70. In a plan view, lead portion 31, lead portion 32 and lead portions 33 protrude from an outer peripheral edge of sealing member 70 along a second direction DR2. Second direction DR2 is a direction orthogonal to first direction DR1 in a plan view. In addition, in a plan view, connection portion 44 and connection portion 45 protrude from the outer peripheral edge of sealing member 70 along first direction DR1. None of lead portion 31, lead portion 32 and lead portions 33 protruding from the outer peripheral edge of sealing member 70 in a plan view overlap with connection portion 44 and connection portion 45 protruding from the outer peripheral edge of sealing member 70 in a plan view.

Sealing member 70 is made of, for example, a thermosetting resin. The thermosetting resin is, for example, an epoxy resin, a phenol resin or the like. Sealing member 70 is formed by transfer molding, compression molding or the like, for example. Sealing member 70 ensures electrical insulation between the members sealed by sealing member 70, and functions as a case of semiconductor device 100A.

### Modification

In the example above, the IGBT is described as an example of semiconductor element 20. However, semiconductor element 20 may be a bipolar transistor, a metal oxide semiconductor field effect transistor (MOSFET) or a gate turn-off thyristor (GTO). Alternatively, semiconductor element 20 may be a diode. When semiconductor element 20 is a diode, semiconductor element 20 is used in a converter portion that converts AC power into DC power, for example.

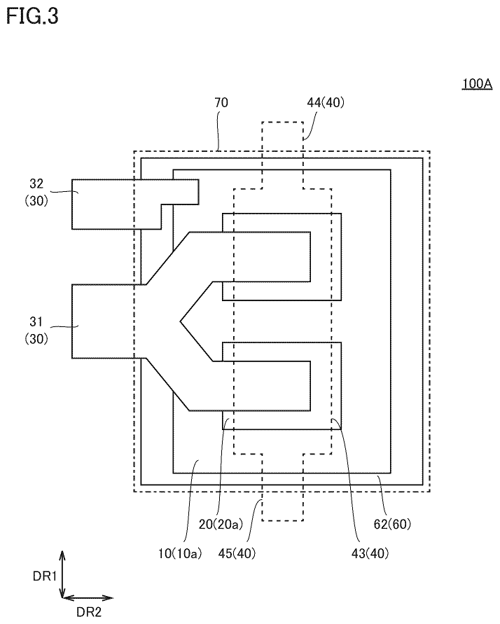

FIG. 3 is a plan view of semiconductor device 100A according to a modification. In FIG. 3, cooler 40 is indicated by a dotted line. As shown in FIG. 3, semiconductor device 100A may have a plurality of semiconductor devices 100A. In this case, lead portion 31 is electrically connected to the first electrode of each of the plurality of semiconductor elements 20.

### (Manufacturing Method for Semiconductor Device 100A)

A manufacturing method for semiconductor device 100A will be described below.

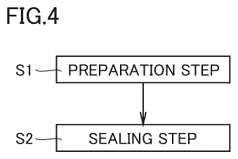

FIG. 4 is a manufacturing process diagram for semiconductor device 100A. As shown in FIG. 4, the manufacturing method for semiconductor device 100A has a preparation step S1 and a sealing step S2.

In preparation step S1, heat spreader 10, semiconductor element 20, lead frame 30, cooler 40, insulating layer 50, and insulating sheet 60 are prepared. At the stage of preparation step S1, semiconductor element 20 is connected to heat spreader 10 by bonding material 80, lead portion 31 is connected to semiconductor element 20 by bonding material 81, lead portion 32 is connected to heat spreader 10 by bonding material 82, and lead portions 33 are connected to semiconductor element 20 by wires 83. At the stage of preparation step S1, insulating layer 50 is interposed between third surface 20a and cooler 40, and insulating sheet 60 (insulating layer 62) is attached to second surface 10b.

Sealing step S2 is performed after preparation step S1. In sealing step S2, firstly, heat spreader 10, semiconductor element 20, lead frame 30, cooler 40, insulating layer 50, and insulating sheet 60 prepared in preparation step S1 are disposed in a mold. At this time, the upper mold presses the portions of lead portion 31, lead portion 32, lead portions 33, connection portion 44, and connection portion 45 that will protrude from sealing member 70 after sealing step S2. Secondly, uncured sealing member 70 is injected into a space between the upper mold and the lower mold. The pressure when sealing member 70 is injected causes insulating layer 50 to come into close contact with semiconductor element 20 and cooler 40, and causes insulating layer 62 to come into close contact with metal layer 61 and heat spreader 10.

Thirdly, sealing member 70 is heated. As a result, sealing member 70 is cured. In addition, as a result of this heating, insulating layer 50 and insulating layer 62 are also cured, and semiconductor element 20 and cooler 40 are bonded by insulating layer 50, and metal layer 61 and heat spreader 10 are bonded by insulating layer 62. As described above, semiconductor device 100A having the structure shown in FIGS. 1 and 2 is manufactured.

### (Effects of Semiconductor Device 100A)

Effects of semiconductor device 100A will be described below.

In semiconductor device 100A, the projected area of cooler 40 is equal to or less than the projected area of heat spreader 10 in a plan view, and thus, downsizing is possible. When the width of cooler 40 (main body portion 43) in first direction DR1 is equal to or less than the width of heat spreader 10, further downsizing is possible.

In addition, in semiconductor device 100A, cooler 40 cools semiconductor element 20 without diffusing the heat generated in semiconductor element 20. Although lead frame 30 (lead portion 31) and insulating layer 50 are present between cooler 40 and semiconductor element 20, these members do not diffuse the heat generated in semiconductor element 20. Therefore, even when the projected area of cooler 40 is equal to or less than the projected area of heat spreader 10 in a plan view, the cooling capacity is less likely to decrease. As described above, according to semiconductor device 100A, high cooling capacity and downsizing can be both achieved.

When none of lead portion 31, lead portion 32 and lead portions 33 protruding from the outer peripheral edge of sealing member 70 in a plan view overlap with connection portion 44 and connection portion 45 protruding from the outer peripheral edge of sealing member 70 in a plan view, an outflow of uncured sealing member 70 can be suppressed only by the upper mold and the lower mold in sealing step S2. Particularly, when an extension direction of lead portion 31, lead portion 32 and lead portions 33 protruding from the outer peripheral edge of sealing member 70 is orthogonal to an extension direction of connection portion 44 and connection portion 45 protruding from the outer peripheral edge of sealing member 70, the shape of the upper mold and the lower mold can be simplified, and breakage or chipping of semiconductor device 100A and the mold at the time of removal from the mold can be suppressed.

### Second Embodiment

A semiconductor device according to a second embodiment will be described. The semiconductor device according to the second embodiment is referred to as a semiconductor device 100B. Here, differences from semiconductor device 100A will be mainly described, and the same description will not be repeated.

### (Configuration of Semiconductor Device 100B)

A configuration of semiconductor device 100B will be described below.

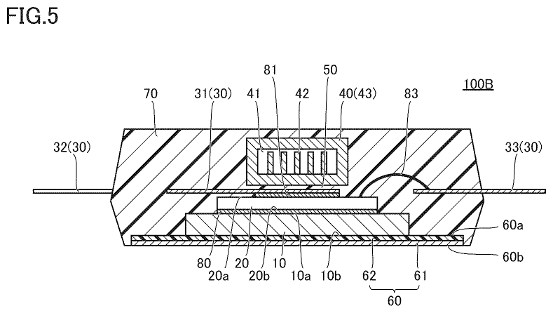

FIG. 5 is a cross-sectional view of semiconductor device 100B. FIG. 5 shows a cross section of semiconductor device 100B at a position corresponding to II-II in FIG. 1. As shown in FIG. 5, semiconductor device 100B has heat spreader 10, semiconductor element 20, lead frame 30, cooler 40, insulating layer 50, insulating sheet 60, and sealing member 70. Semiconductor device 100B further has bonding material 80, bonding material 81 and bonding material 82 (not shown), and wire 83. In these respects, the configuration of semiconductor device 100B is the same as the configuration of semiconductor device 100A.

In semiconductor device 100B, sealing member 70 is filled between third surface 20a and cooler 40 (between lead portion 31 and cooler 40), and a portion of sealing member 70 filled between third surface 20a and cooler 40 functions as insulating layer 50. In this respect, the configuration of semiconductor device 100B is different from the configuration of semiconductor device 100A.

### (Manufacturing Method for Semiconductor Device 100B)

A manufacturing method for semiconductor device 100B will be described below.

The manufacturing method for semiconductor device 100B has preparation step S1 and sealing step S2. In this respect, the manufacturing method for semiconductor device 100B is the same as the manufacturing method for semiconductor device 100A.

In the manufacturing method for semiconductor device 100B, in preparation step S1, insulating layer 50 is not interposed between semiconductor element 20 and cooler 40. In addition, in the manufacturing method for semiconductor device 100B, when heat spreader 10, semiconductor element 20, lead frame 30, cooler 40, and insulating sheet 60 are disposed in the mold, there is a space between semiconductor element 20 and cooler 40. Sealing member 70 injected into the mold flows into this space. In these respects, the manufacturing method for semiconductor device 100B is different from the manufacturing method for semiconductor device 100A.

### (Effects of Semiconductor Device 100B)

Effects of semiconductor device 100B will be described below.

In semiconductor device 100B, a part of sealing member 70 can function as insulating layer 50, which eliminates the need for providing insulating layer 50 separately from sealing member 70, and thus, the number of the used components can be reduced.

When insulating layer 50 is provided separately from sealing member 70, adhesiveness between semiconductor element 20 and cooler 40 may become insufficient unless insulating layer 50 is cured at appropriate timing in sealing step S2. In semiconductor device 100B, a part of sealing member 70 functions as insulating layer 50, and thus, a decrease in adhesiveness between semiconductor element 20 and cooler 40 caused by insulating layer 50 not being cured at appropriate timing can be suppressed.

### Third Embodiment

A semiconductor device according to a third embodiment will be described. The semiconductor device according to the third embodiment is referred to as a semiconductor device 100C. Here, differences from semiconductor device 100A will be mainly described, and the same description will not be repeated.

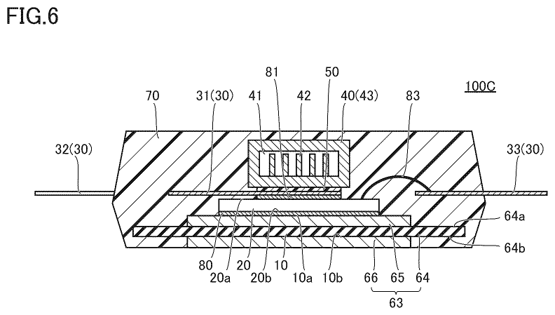

FIG. 6 is a cross-sectional view of semiconductor device 100C. FIG. 6 shows a cross section of semiconductor device 100C at a position corresponding to II-II in FIG. 1. As shown in FIG. 6, semiconductor device 100B has heat spreader 10, semiconductor element 20, lead frame 30, cooler 40, insulating layer 50, and sealing member 70. Semiconductor device 100C further has bonding material 80, bonding material 81 and bonding material 82 (not shown), and wire 83. In these respects, the configuration of semiconductor device 100C is the same as the configuration of semiconductor device 100A.

Semiconductor device 100C has an insulating substrate 63, instead of insulating sheet 60. Insulating substrate 63 has an insulating base body 64, an electrically conductive layer 65 and an electrically conductive layer 66. Insulating base body 64 has a seventh surface 64a and an eighth surface 64b. Seventh surface 64a and eighth surface 64b are end faces of insulating base body 64 in the thickness direction. Eighth surface 64b is opposite to seventh surface 64a. Insulating base body 64 is made of, for example, a ceramic material such as alumina, aluminum nitride and silicon nitride. A thickness of insulating base body 64 is selected as appropriate from the viewpoint of ensuring a required breakdown voltage.

Electrically conductive layer 65 is disposed on seventh surface 64a. Electrically conductive layer 66 is disposed on eighth surface 64b. Each of electrically conductive layer 65 and electrically conductive layer 66 is made of, for example, copper, aluminum or the like. In semiconductor device 100C, semiconductor element 20 is disposed such that fourth surface 20b faces electrically conductive layer 65. In semiconductor device 100C, fourth surface 20b and electrically conductive layer 65 are electrically connected to each other by bonding material 80, and electrically conductive layer 65 and lead portion 32 are electrically connected to each other by bonding material 82. That is, in semiconductor device 100C, electrically conductive layer 65 functions as heat spreader 10. A thickness of electrically conductive layer 65 and a thickness of electrically conductive layer 66 are selected as appropriate from the viewpoint of ensuring the cooling capacity. The thickness of electrically conductive layer 65 and the thickness of electrically conductive layer 66 are preferably equal to each other from the viewpoint of suppressing warpage of insulating substrate 63.

In semiconductor device 100C as well, the projected area of cooler 40 is equal to or less than the projected area of heat spreader 10 in a plan view, similarly to semiconductor device 100A. Therefore, high cooling capacity and downsizing can be both achieved.

### Fourth Embodiment

A semiconductor device according to a fourth embodiment will be described. The semiconductor device according to the fourth embodiment is referred to as a semiconductor device 100D. Here, differences from semiconductor device 100A will be mainly described, and the same description will not be repeated.

### (Configuration of Semiconductor Device 100D)

A configuration of semiconductor device 100D will be described below.

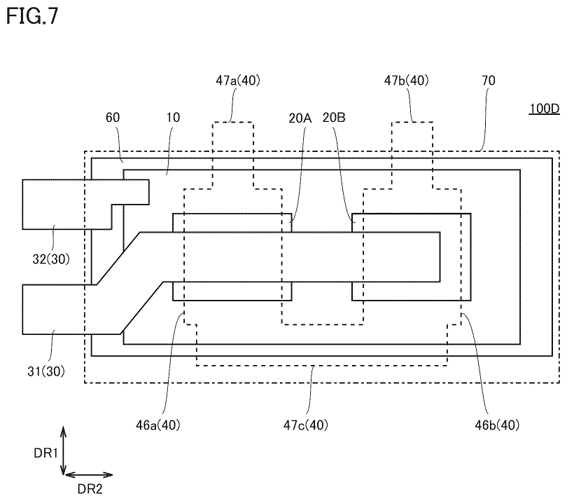

FIG. 7 is a plan view of semiconductor device 100D. As shown in FIG. 7, semiconductor device 100D has heat spreader 10, semiconductor element 20, lead frame 30, cooler 40, insulating layer 50, insulating sheet 60, and sealing member 70. Semiconductor device 100D further has bonding material 80, bonding material 81 and bonding material 82 (not shown). In these respects, the configuration of semiconductor device 100D is the same as the configuration of semiconductor device 100A.

Semiconductor device 100D has a plurality of semiconductor elements 20. More specifically, semiconductor device 100D has a semiconductor element 20A and a semiconductor element 20B. Semiconductor element 20A and semiconductor element 20B are disposed side by side along second direction DR2 in a plan view. In semiconductor device 100D, lead portion 31 is electrically connected to third surface 20a of semiconductor element 20A and third surface 20a of semiconductor element 20B by bonding material 81. In semiconductor device 100D, cooler 40 has a main body portion 46a and a main body portion 46b, and a connection portion 47a, a connection portion 47b and a connection portion 47c.

Main body portion 46a and main body portion 46b are disposed to face third surface 20a of semiconductor element 20A and third surface 20a of semiconductor element 20B, respectively, with insulating layer 50 interposed therebetween. Connection portion 47a is connected to one end of main body portion 46a in first direction DR1. Connection portion 47b is connected to one end of main body portion 46b in first direction DR1. Connection portion 47a and connection portion 47b protrude from only one side of the outer peripheral edge of sealing member 70 in a plan view along first direction DR1. Connection portion 47c connects the other end of main body portion 46a in first direction DR1 and the other end of main body portion 46b in first direction DR1. Connection portion 47c is not exposed from sealing member 70. In these respects, the configuration of semiconductor device 100D is different from the configuration of semiconductor device 100A.

### (Effects of Semiconductor Device 100D)

Effects of semiconductor device 100D will be described below.

In semiconductor device 100D, even when semiconductor element 20 is located at a displaced position, high cooling capacity and downsizing can be both achieved. In addition, in semiconductor device 100D, connection portion 47a and connection portion 47b protrude from only one side of the outer peripheral edge of sealing member 70 in a plan view. Therefore, even when there is an obstacle around semiconductor device 100D in a case of a device where semiconductor device 100D is placed, semiconductor device 100D can be disposed in proximity to the obstacle and the device where semiconductor device 100D is placed can be downsized.

### Fifth Embodiment

A semiconductor device according to a fifth embodiment will be described. The semiconductor device according to the fifth embodiment is referred to as a semiconductor device 100E. Here, differences from semiconductor device 100D will be mainly described, and the same description will not be repeated.

### (Configuration of Semiconductor Device 100E)

A configuration of semiconductor device 100E will be described below.

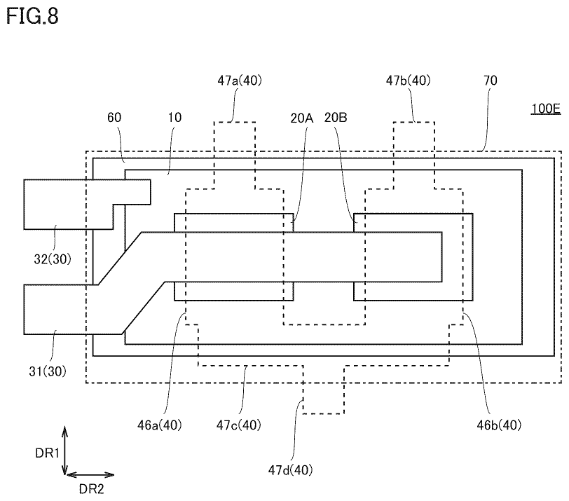

FIG. 8 is a plan view of semiconductor device 100E. As shown in FIG. 8, semiconductor device 100E has heat spreader 10, a plurality of semiconductor elements 20 (semiconductor element 20A and semiconductor element 20B), lead frame 30, cooler 40, insulating layer 50, insulating sheet 60, and sealing member 70. Semiconductor device 100E further has bonding material 80, bonding material 81 and bonding material 82 (not shown). In these respects, the configuration of semiconductor device 100E is the same as the configuration of semiconductor device 100D.

In semiconductor device 100E, cooler 40 further has a connection portion 47d. Connection portion 47d is connected to connection portion 47c. Connection portion 47d protrudes from the outer peripheral edge of sealing member 70 in a plan view along first direction DR1. A side of the outer peripheral edge of sealing member 70 from which connection portion 47d protrudes is located opposite in first direction DR1 to a side of the outer peripheral edge of sealing member 70 from which connection portion 47a and connection portion 47b protrude. That is, in semiconductor device 100E, the number of the connection portions of cooler 40 protruding from the outer peripheral edge of sealing member 70 in a plan view is three.

The refrigerant is, for example, supplied from a hose connected to connection portion 47d, and branches off at a connection portion that connects flow path 41 in connection portion 47d and flow path 41 in connection portion 47c. One of the branched refrigerant flows through flow path 41 in connection portion 47c, flow path 41 in main body portion 46a, and a flow path in connection portion 47a, and is discharged from the hose connected to connection portion 47a. In addition, the other of the branched refrigerant flows through flow path 41 in connection portion 47c, flow path 41 in main body portion 46b, and the flow path in connection portion 47b, and is discharged from the hose connected to connection portion 47a. In these respects, the configuration of semiconductor device 100E is different from the configuration of semiconductor device 100D.

### Modification

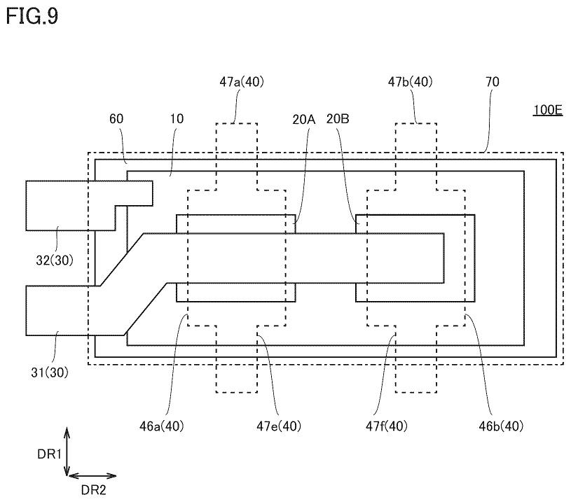

FIG. 9 is a plan view of semiconductor device 100E according to a modification. As shown in FIG. 9, in semiconductor device 100E, cooler 40 may have a connection portion 47e and a connection portion 47f, instead of connection portion 47d. Connection portion 47e and connection portion 47f are connected to the other end of main body portion 46a in first direction DR1 and the other end of main body portion 46b in first direction DR1, respectively. Connection portion 47e and connection portion 47f protrude from the outer peripheral edge of sealing member 70 in a plan view along first direction DR1.

A side of the outer peripheral edge of sealing member 70 from which connection portion 47e and connection portion 47f protrude is located opposite in first direction DR1 to a side of the outer peripheral edge of sealing member 70 from which connection portion 47a and connection portion 47b protrude. That is, in semiconductor device 100E, the number of the connection portions of cooler 40 protruding from the outer peripheral edge of sealing member 70 in a plan view may be three or more.

When cooler 40 has connection portion 47e and connection portion 47f, the refrigerant is supplied from a hose connected to connection portion 47e, flows through flow path 41 in connection portion 47e, flow path 41 in main body portion 46a, and flow path 41 in connection portion 47a, and is discharged from the hose connected to connection portion 47a. The refrigerant is supplied from a hose connected to connection portion 47f, flows through flow path 41 in connection portion 47f, flow path 41 in main body portion 46b, and flow path 41 in connection portion 47b, and is discharged from the hose connected to connection portion 47b. As described above, in semiconductor device 100D, cooler 40 may have a plurality of independent flow paths 41.

### (Effects of Semiconductor Device 100E)

Effects of semiconductor device 100E will be described below.

In semiconductor device 100E, flow path 41 of cooler 40 can branch off in the middle, and the plurality of independent flow paths 41 can be provided in cooler 40. Therefore, in semiconductor device 100E, higher cooling capacity is possible while downsizing is possible.

### Sixth Embodiment

The present embodiment represents application of the semiconductor device according to any one of the above-described first to fifth embodiments to a power conversion device. Although the present disclosure is not limited to a particular power conversion device, application of the present disclosure to a three-phase inverter will be described below as a sixth embodiment. A power conversion system according to the sixth embodiment is referred to as a power conversion system 200.

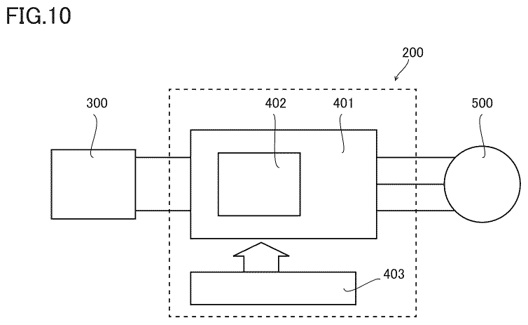

FIG. 10 is a block diagram showing a configuration of power conversion system 200. As shown in FIG. 10, the power conversion system is constituted of a power supply 300, a power conversion device 400 and a load 500. Power supply 300 is a DC power supply and supplies DC power to power conversion device 400. Power supply 300 can be configured by a variety of types, and can be configured by a DC system, a solar battery or a storage battery, for example. Power supply 300 may be configured by a rectifier circuit or an AC/DC converter connected to an AC system. Alternatively, power supply 300 may be configured by a DC/DC converter that converts DC power output from the DC system into prescribed power.

Power conversion device 400 is a three-phase inverter connected between power supply 300 and load 500, and converts DC power supplied from power supply 300 into AC power and supplies the AC power to load 500. As shown in FIG. 10, power conversion device 400 includes a main conversion circuit 401 that converts DC power into AC power and outputs the AC power, and a control circuit 403 that outputs, to main conversion circuit 401, a control signal for controlling main conversion circuit 401.

Load 500 is a three-phase electric motor driven by the AC power supplied from power conversion device 400. Load 500 is not limited to a specific application, and load 500 is an electric motor mounted on various types of electric devices and is used as an electric motor for a hybrid vehicle, an electric vehicle, a railroad vehicle, an elevator, or an air-conditioning device, for example.

Details of power conversion device 400 will be described below. Main conversion circuit 401 includes a switching element and a freewheeling diode (not shown). When the switching element is switched, DC power supplied from power supply 300 is converted into AC power, which is supplied to load 500. While there are various types of specific circuit configurations for main conversion circuit 401, main conversion circuit 401 according to the present embodiment is a two-level three-phase full-bridge circuit and can be formed of six switching elements and six freewheeling diodes that are in antiparallel with the switching elements, respectively. At least one of the switching elements and the freewheeling diodes of main conversion circuit 401 is a switching element or a freewheeling diode of a semiconductor module 402 corresponding to the semiconductor device according to any one of the above-described first to fifth embodiments. The six switching elements have every two switching elements connected in series to form upper and lower arms, and the upper and lower arms configure the full bridge circuit's phases (a U phase, a V phase and a W phase). Output terminals of the upper and lower arms, i.e., three output terminals of main conversion circuit 401 are connected to load 500.

Main conversion circuit 401 includes a drive circuit (not shown) that drives each switching element, and main conversion circuit 401 may have the drive circuit built into semiconductor module 402, or may include the drive circuit separately from semiconductor module 402. The drive circuit generates a drive signal for driving the switching elements of main conversion circuit 401, and supplies the drive signal to a control electrode of each switching element of main conversion circuit 401. Specifically, in accordance with the control signal from below-described control circuit 403, a drive signal for bringing a switching element into an on state and a drive signal for bringing a switching element into an off state are output to the control electrode of each switching element. When the switching element is maintained in the on state, the drive signal is a voltage signal (ON signal) equal to or higher than a threshold voltage of the switching element. When the switching element is maintained in the off state, the drive signal is a voltage signal (OFF signal) equal to or lower than the threshold voltage of the switching element.

Control circuit 403 controls the switching elements of main conversion circuit 401 such that desired power is supplied to load 500. Specifically, control circuit 403 calculates a time for which each switching element of main conversion circuit 401 should be turned on (ON time) based on the power to be supplied to load 500. For example, control circuit 403 can control main conversion circuit 401 by PWM control by which an ON time of a switching element is modulated in accordance with a voltage to be output. Control circuit 403 outputs a control command (control signal) to the drive circuit of main conversion circuit 401 such that the ON signal is output to a switching element to be turned on at each point in time and the OFF signal is output to a switching element to be turned off at each point in time. In response to this control signal, the drive circuit outputs the ON signal or the OFF signal as the drive signal to the control electrode of each switching element.

In power conversion device 400, the semiconductor device according to any one of the above-described first to fifth embodiments is applied as semiconductor module 402 that constitutes main conversion circuit 401, and thus, it is possible to reduce a current density in the current path from semiconductor element 20, while suppressing generation of thermal stress around semiconductor element 20.

Although the present embodiment has described an example where the present disclosure is applied to a two-level three-phase inverter, the present disclosure is not limited thereto, and is applicable to various power conversion devices. Although the present embodiment has described a two-level power conversion device, a three-level power conversion device or a multi-level power conversion device may be adopted, and when the power conversion device supplies power to a single-phase load, the present disclosure may be applied to a single-phase inverter. When the power conversion device supplies power to a DC load or the like, the present disclosure is also applicable to a DC/DC converter or an AC/DC converter.

The power conversion device to which the present disclosure is applied is not limited to the above case where the load is an electric motor. For example, the power conversion device can also be used as a power supply device for an electric discharge machine, a laser beam machine, an induction heating cooking device, or a non-contact power feeding system, and furthermore can also be used as a power conditioner for a solar power generation system, a power storage system, or the like.

It should be understood that the embodiments disclosed herein are illustrative and non-restrictive in every respect. The basic scope of the present disclosure is defined by the terms of the claims, rather than the embodiments above, and is intended to include any modifications within the scope and meaning equivalent to the terms of the claims.

### REFERENCE SIGNS LIST

10 heat spreader; 10a first surface; 10b second surface; 20, 20A, 20B semiconductor element; 20a third surface; 20b fourth surface; 30 lead frame; 31, 32, 33 lead portion; 40 cooler; 41 flow path; 42 fin; 43 main body portion; 44, 45 connection portion; 46a, 46b main body portion; 47a, 47b, 47c, 47d, 47e, 47f connection portion; 50 insulating layer; 60 insulating sheet; 60a fifth surface; 60b sixth surface; 61 metal layer; 62 insulating layer; 63 insulating substrate; 64 insulating base body; 64a seventh surface; 64b eighth surface; 65, 66 electrically conductive layer; 70 sealing member; 80, 81, 82 bonding material; 83 wire; 100A, 100B, 100C, 100D, 100E semiconductor device; 200 power conversion system; 300 power supply; 400 power conversion device; 401 main conversion circuit; 402 semiconductor module; 403 control circuit; 500 load; DR1 first direction; DR2 second direction; S1 preparation step; S2 sealing step.

1. A semiconductor device comprising:
a heat spreader;
a semiconductor element;
a cooler;
an insulating layer;
a sealing member; and
a lead frame, wherein
the heat spreader has a first surface and a second surface opposite to the first surface,
the semiconductor element has a third surface and a fourth surface opposite to the third surface, and is disposed such that the fourth surface faces the first surface,
the cooler is disposed to face the first surface with the insulating layer interposed therebetween,
a flow path through which refrigerant flows is provided inside the cooler,
the sealing member seals the heat spreader, the semiconductor element and the cooler,
in a plan view, a projected area of the cooler is equal to or less than a projected area of the heat spreader,
the lead frame is electrically connected to the third surface,
the cooler has at least one connection portion,
the lead frame has a lead portion,
the connection portion and the lead portion protrude from an outer peripheral edge of the sealing member in a plan view and do not overlap with each other, and
in a plan view, a direction in which the connection portion extends is orthogonal to a direction in which the lead portion extends.

2. The semiconductor device according to claim 1, wherein
in a cross-sectional view orthogonal to a direction of the refrigerant flowing inside the flow path on the semiconductor element, a width of the flow path on the semiconductor element is equal to or less than a width of the heat spreader.

3. The semiconductor device according to claim 1, with respect to all of the lead portions that the lead frame has, a direction in which the connection portion extends is orthogonal to a direction in which the lead portion extends.

4. (canceled)

5. The semiconductor device according to claim 1, wherein
the connection portion protrudes from only one side of the outer peripheral edge of the sealing member in a plan view.

6. The semiconductor device according to claim 1, wherein
the number of the connection portion protruding from the outer peripheral edge of the sealing member in a plan view is three or more.

7. The semiconductor device according to claim 1, wherein
the insulating layer is constituted by the sealing member filled between the first surface and the cooler.

8. The semiconductor device according to claim 1, further comprising an insulating sheet, wherein
the heat spreader is disposed on the insulating sheet such that the second surface faces the insulating sheet, and
the sealing member further seals the insulating sheet.

9. The semiconductor device according to claim 1, further comprising an insulating base body, wherein
the heat spreader is disposed on the insulating layer such that the second surface faces the insulating base body,
the heat spreader and the insulating base body constitute an insulating substrate, and
the sealing member further seals the insulating base body.

10. A power conversion device comprising:
a main conversion circuit having the semiconductor device as recited in claim 1, to convert input power and output the converted input power; and
a control circuit to output, to the main conversion circuit, a control signal for controlling the main conversion circuit.
